(19) United States
(12) Patent Application Publication
(10) Pub. No.: US 2023/0131213 A1
(43) Pub. Date: Apr. 27, 2023

(54) FILM FORMING METHOD AND FILM FORMING SYSTEM

(71) Applicant: Tokyo Electron Limited, Tokyo (JP)

(72) Inventors: Isao GUNJI, Yamanashi (JP); Masahiro OKA, Yamanashi (JP); Minoru HONDA, Yamanashi (JP); Takashi KOBAYASHI, Yamanashi (JP)

(21) Appl. No.: 17/973,934

(22) Filed: Oct. 26, 2022

(30) Foreign Application Priority Data
Oct. 27, 2021 (JP) 2021-175804
Sep. 21, 2022 (JP) 2022-150161

(51) Int. Cl. H01L 21/02; H01L 21/311; H01L 21/3205; H01L 21/3213; H01J 37/32; C23C 16/50; C23C 16/56; C23C 16/34; C23C 16/36; C23C 16/30; C23C 16/24; C23C 16/52

(52) U.S. Cl. CPC H01L 21/02274; H01L 21/02126; H01L 21/0214; H01L 21/02167; H01L 21/0217; H01L 21/31116; H01L 21/32055; H01L 21/32135; H01J 37/32733; H01J 37/32449; H01J 37/32816; C23C 16/50; C23C 16/56; C23C 16/345; C23C 16/36; C23C 16/308; C23C 16/24; C23C 16/52; H01J 2237/334; H01J 2237/3321

(57) ABSTRACT

A film forming method includes: preparing a substrate having a recess within a processing container; forming a silicon-containing film on the substrate by activating a silicon-containing gas with plasma and supplying the activated silicon-containing gas to the substrate; partially modifying the silicon-containing film after the silicon-containing film closes an opening of the recess; and selectively etching the modified silicon-containing film.

### CROSS-REFERENCE TO RELATED APPLICATIONS

This application is based upon and claims the benefit of priority from Japanese Patent Application Nos. 2021-175804 and 2022-150161, filed on Oct. 27, 2021 and Sep. 21, 2022, respectively, the entire contents of which are incorporated herein by reference.

### TECHNICAL FIELD

The present disclosure relates to a film forming method and a film forming system.

### BACKGROUND

With the miniaturization of semiconductor devices, there is a demand for filling a recess having a high aspect ratio with a high-quality film without generating voids or seams.

For example, Patent Document 1 discloses a film forming method including the step of forming a silicon oxide film on a substrate by supplying a silicon-containing gas and an oxygen-containing gas, and the step of etching the silicon oxide film by supplying a hydrofluoric acid gas and an ammonia gas, wherein the film forming step and the etching step are alternately repeated.

For example, Patent Document 2 discloses a film forming method including a first step in which a film forming process for depositing an insulating film on a substrate and wiring lines and an etching process for performing sputter-etching with Ar and ions are simultaneously performed to form voids between the wiring lines, and then a second step in which the insulating films on the wiring lines and the insulating film between the wiring lines are selectively etched to flatten the insulating films on the wiring lines and form an opening between the wiring lines, wherein the first step and the second step are repeated.

### PRIOR ART DOCUMENTS

### Patent Documents

Patent Document 1: Japanese Laid-Open Publication No. 2012-199306
Patent Document 2: Japanese Laid-Open Publication No. 2003-37103
Patent Document 3: Japanese Laid-Open Publication No. 2007-180418

### SUMMARY

According to one embodiment of the present disclosure, there is provided a film forming method including: preparing a substrate having a recess within a processing container; forming a silicon-containing film on the substrate by activating a silicon-containing gas with plasma and supplying the activated silicon-containing gas to the substrate; partially modifying the silicon-containing film after the silicon-containing film closes an opening of the recess; and selectively etching the modified silicon-containing film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method ST according to an embodiment.

FIGS. 2A to 2F are explanatory views of the film forming method according to an embodiment.

FIG. 3 is a diagram showing the relationship between film forming time and film thickness according to an embodiment.

FIG. 4 is a diagram showing the relationship between film forming time and pressure according to an embodiment.

FIG. 5 is a diagram showing the relationship between film forming time and gas flow rate ratio according to an embodiment.

FIG. 6 is a view illustrating a configuration example of a film forming system according to an embodiment.

FIG. 7 is a view illustrating a configuration example of a film forming apparatus according to an embodiment.

FIG. 8 is a view illustrating a configuration example of another processing apparatus according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In each of the drawings, the same components may be denoted by the same reference numerals, and redundant descriptions thereof may be omitted.

### [Film Forming Method ST]

With the miniaturization of semiconductor devices in the steps of a semiconductor manufacturing process, there is a demand for filling a recess having a high aspect ratio with a high-quality film without generating voids or seams. An atomic layer deposition (ALD) in the related arts may include problems such as low throughput, the occurrence of seams and voids, shape deformation of a recess in a post-process, and deterioration of electrical properties of a film.

In addition, conventional high-density plasma chemical vapor deposition (high-density plasma (HDP) CVD) may include problems such as reduction of a critical dimension (CD), deterioration in filling performance of a film in a recess due to a high aspect ratio, deformation of a substrate structure due to ion implantation, and deterioration of film quality.

In addition, a flowable chemical vapor deposition (FCVD) in the related arts may include problems such as complication of a flowable film forming step and a cure treatment step, and deterioration of electrical characteristics due to a film quality gradient in a film forming depth direction.

The present disclosure proposes a film forming method capable of solving the above problems and improving the filling performance of a silicon-containing film in a recess formed in a substrate.

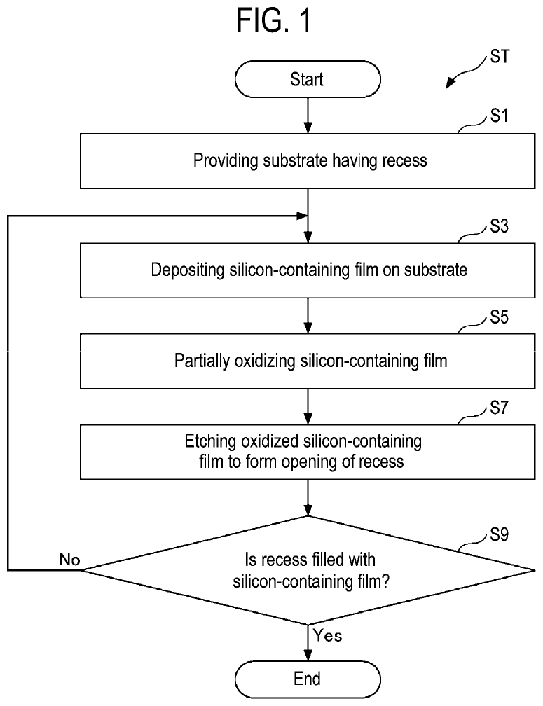

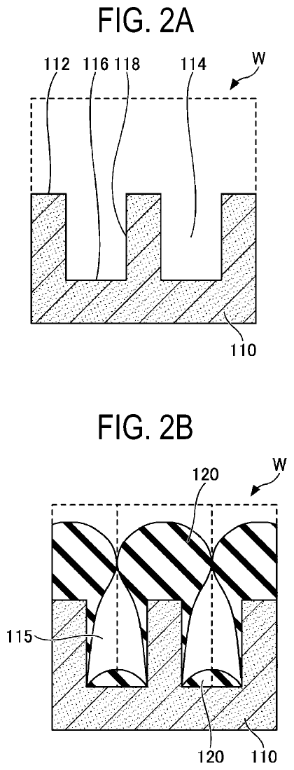

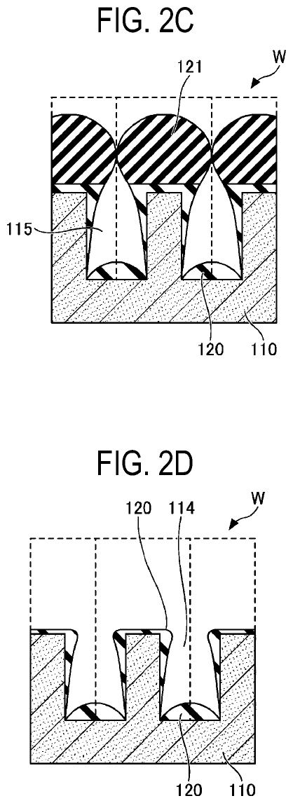

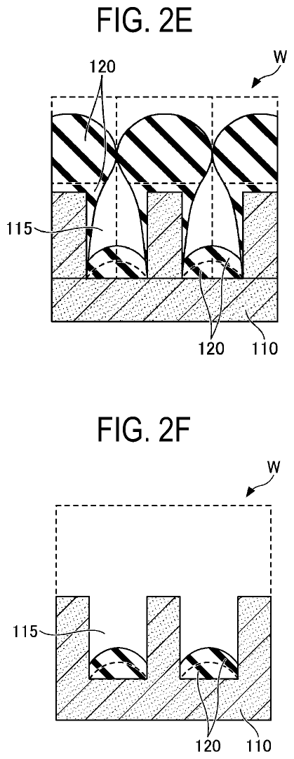

FIG. 1 is a flowchart illustrating a film forming method ST according to an embodiment. FIGS. 2A to 2F are explanatory views of the film forming method ST according to an embodiment. The film forming method ST of the present disclosure forms a silicon-containing film in a recess formed in a substrate W, an example of which is a wafer (semiconductor wafer).

### (Substrate Preparation Step S1)

First, in the substrate preparation step S1 of FIG. 1, the step of providing a substrate W in a processing container of a processing apparatus is performed. FIG. 2A illustrates an example of a substrate W having a recess 114. The substrate W has recesses 114 on the silicon substrate 110. The recesses 114 in the substrate W each have a trench structure and include a top surface 112, a bottom surface 116 and side surfaces 118. The recesses 114 may be holes or lines.

### (Film Forming Step S3)

Next, in the film forming step S3 of FIG. 1, a silicon-containing film is deposited in the recesses 114 of the substrate W. In the present disclosure, a silicon-containing film is formed by CVD. Specifically, a silicon-containing gas is activated by plasma and supplied to the substrate W to form a silicon-containing film on the substrate W.

Here, a silicon nitride film (SiN) is deposited as an example of a silicon-containing film. In this case, a processing gas including a silicon-containing gas and a nitrogen-containing gas is supplied into a processing container of a processing apparatus to generate plasma, and gas species activated by the plasma are chemically reacted to form a silicon nitride film. The silicon-containing gas may be silane (SiH₄) gas, and the nitrogen-containing gas may be ammonia (NH₃) gas. However, the types of silicon-containing gas and nitrogen-containing gas are not limited thereto. For example, the nitrogen-containing gas may be nitrogen (N₂) gas. In the film forming step S3, films are formed under the condition that silicon nitride films are preferentially formed near the top surfaces 112 of the recesses 114 and the bottom surfaces 116 of the recesses 114, and the silicon nitride films formed near the top surfaces 112 of the recesses 114 close the openings of the recesses 114. The process conditions of the film forming step S3 are as follows.

### <Process Conditions for Film Forming Step S3>

Film forming gases: SiH₄, N₂, and Ar

Pressure: 5 Pa to 50 Pa

Plasma power: 500 W to 4,500 W

SiH₄ gas, NH₃ gas, and Ar gas are supplied into the processing container, activated by plasma, and supplied to the substrate W, thereby forming a silicon nitride film on the substrate W.

FIG. 2B illustrates the state in which silicon nitride films 120 are deposited on the bottom surfaces 116 and the top surfaces 112 of the recesses 114 and the openings of the recesses 114 are closed by the silicon nitride films 120. In the film forming step S3, film formation is performed under the process condition that the silicon nitride films 120 are preferentially formed on the top surfaces 112 and the bottom surfaces 116 of the recesses, and the silicon nitride films 120 are not formed on the side surfaces 118 as much as possible. That is, the films are not formed conformally in the film forming step S3. As such process conditions, for example, the pressure inside the processing container is increased. In addition, for example, the flow rate of the SiH₄ gas and/or the NH₃ gas is increased relative to the total flow rate of a mixed gas of the SiH₄ gas, the NH₃ gas, Ar gas, and the like supplied into the processing container.

FIG. 2B illustrates the state in which the silicon nitride films 120 are deposited on the bottom surfaces 116 and the top surfaces 112 of the recesses 114, and the silicon nitride films 120 deposited on the top surfaces 112 become mushroom-shaped and are in contact with the adjacent silicon nitride films 120 to close the openings of the recesses 114. When the silicon nitride films 120 are preferentially formed until the openings of the recesses 114 are closed, the silicon nitride films 120 are also formed on the bottom surfaces 116 of the recesses 114, and voids 115 are formed thereabove.

### (Oxidation Step S5 (Modifying Step))

Next, in the oxidation step S5 of FIG. 1, the silicon nitride films 120 including the silicon nitride films 120 closing the openings of the recesses 114 are partially oxidized. The oxidation step S5 is an example of the step of partially modifying the silicon nitride films 120.

In the oxidation step S5, the silicon nitride films 120 may be partially oxidized. Process conditions for the oxidation step S5 when the silicon nitride films 120 are oxidized are represented below. In the oxidation step S5, plasma may be or may not be used, as described below.

### <Process Conditions of Oxidation Step S5>

Oxidizing gases: O₃, O₂, or nitrous oxide (N₂O)

Presence or absence of plasma: in the case of O₃, the substrate is exposed to O₃ gas) (no plasma is used)

O₂ or N₂O is activated by plasma (using plasma)

Temperature of stage (substrate): 200 degrees C. to 500 degrees C.

Pressure: 5 Pa to 400 Pa

Plasma power: 500 W to 4500 W (when plasma is used)

As a result, the silicon nitride films 120 deposited on the top surfaces 112 are partially oxidized and turned into silicon oxide (SiOₓ) films 121. This step is continued until at least the portions of the silicon nitride films 120 closing the openings of the recesses 114 are oxidized. FIG. 2C illustrates the state in which the silicon nitride films 120 are partially oxidized and modified (degenerated) into silicon oxide films 121. The silicon nitride films 120 closing the openings of the recesses 114 are partially oxidized and modified into the silicon oxide films 121. Since the thicknesses of the silicon nitride films formed in the vicinities of the top surfaces 112 are increased, the oxidation step S5 is preferably performed, for example, under the condition that the pressure is high and the flow rate of the oxidizing gas is large. For example, when plasma is used, the condition that the pressure is high and the plasma power is high is suitable. The processing temperature is preferably equal to or higher than that of the film forming step S3.

The oxidized portions are the silicon nitride films 120 in the vicinities of the top surfaces 112 (for example, the layers above the top surfaces 112). Since the openings of the recesses 114 are closed, the silicon nitride films 120 formed at the bottoms of the recesses 114 may be prevented from being oxidized by the oxidation step S5. Therefore, according to this step, it is possible to modify the silicon nitride films 120 closing the openings of the recesses 114 into the silicon oxide films 121 while protecting (without modifying) the silicon nitride films 120 at the bottoms of the recesses 114. In this manner, only the silicon nitride films 120 near the top surfaces 112 of the recesses 114 are modified (oxidized) into the silicon oxide films 121. This facilitates selective etching of the silicon oxide films 121 closing the openings of the recesses 114 in the etching step S7, which will be described later.

### (Etching Step S7 (First Etching Step))

Next, in the etching step S7 of FIG. 1, the modified silicon oxide films 121 are selectively etched. In the case of the silicon nitride films 120 and the silicon oxide films 121, the silicon oxide films 121 are easily etched under the following process conditions. This makes it possible to selectively etch the silicon oxide films 121 relative to the silicon nitride films 120 and to selectively remove the silicon oxide films 121. As a result, the silicon nitride films 120 on the bottom surfaces 116 of the recesses 114 are not removed even in this etching step S7.

By removing the silicon oxide films 121, the openings of the recesses 114 are formed again. FIG. 2D illustrates the state in which the silicon oxide films 121 are removed, the openings of the recesses 114 are opened again, and the non-oxidized silicon nitride films 120 remain. In the etching step S7, the silicon oxide films 121 are removed without using plasma. Process conditions for the etching step S7 are illustrated below. This etching step is also described in detail in Patent Document 3.

### <Process Conditions of Etching Step S7>

COR etching gases: NH₃ and hydrogen fluoride (HF)

Temperature of stage (substrate) in COR step: 20 degrees C. to 90 degrees C.

Pressure in COR step: 5 Pa to 133 Pa

As a result, the silicon oxide films 121 are selectively etched relative to the silicon nitride films 120. The etching step S7 includes a chemical oxide remover (COR) step and a post-heat treatment (PHT) step. In the COR step, a fluorine-containing gas and a nitrogen-containing gas are supplied to the substrate W, and the fluorine-containing gas, the nitrogen-containing gas, and the silicon oxide films 121 are reacted to form an easily vaporizable substance. In the PHT step, the formed vaporizable substance is heated to be vaporized and removed. For example, by using NH₃ gas and HF gas as reaction gases in the COR step and the PHT step, the silicon oxide films 121 are removed by using the following chemical reaction. An example of the fluorine-containing gas is HF gas, and an example of the nitrogen-containing gas is NH₃ gas, but the present disclosure is not limited thereto.

In the COR step, the silicon oxide films 121 are changed into an easily vaporizable substance without using plasma as illustrated in the following chemical reaction formula. By not using plasma, it is possible to reduce degeneration or damage of the silicon nitride films 120 formed in the recesses 114.

### <Chemical Reaction Formula of COR Step/Formation of Easily Vaporizable Product>

SiO₂ (solid)+2NH₃ (gas)+6HF (gas)→(NH₄)₂SiF₆ (solid, easily vaporizable product)+2H₂O (gas)

When the silicon oxide films 121 are exposed to NH₃ gas and HF gas, the films are turned into ammonium silicofluoride ((NH₄)₂SiF₆) as an easily vaporizable product.

In the PHT step, the ammonium silicofluoride formed by the COR step is heat-treated as shown in the following chemical reaction formula to vaporize and remove the ammonium silicofluoride as SiF₄, HF, and NH₃. In order to vaporize ammonium silicofluoride in this manner, it is preferable to control the temperature of the stage on which the substrate is placed or the temperature of the substrate to 50 degrees C. or higher in the PHT step. Alternatively, the ammonium silicofluoride may be vaporized by supplying a high-temperature heating gas as described in Patent Document 3.

### <Chemical Reaction Formula of PHT Step>

(NH₄)₂SiF₆→SiF₄↑+2NH₃↑+2HF↑

As a result, it is possible to remove the silicon oxide films 121 above the top surfaces 112 including the silicon nitride films 120 closing the openings of the recesses 114 without using plasma. This makes it possible to open the openings of the recesses 114 again, and to form the silicon nitride films 120 bottom-up from the bottom surfaces 116 in the next film forming step S3.

### (Filling Determination Step S9)

Next, in the filling determination step S9 of FIG. 1, it is determined whether the recesses 114 are filled with the silicon nitride films 120. The processes illustrated in steps S3 to S7 are performed until it is determined that the recesses 114 are filled with the silicon nitride films 120. As a result, the processes of the film forming step S3, the oxidation step S5, and the etching step S7 included in steps S3 to S7 are repeated. FIG. 2E illustrates the state after the next film forming step S3 has been executed since it was determined that voids 115 were formed and the recesses 114 was not completely filled with the silicon nitride films 120 (“No” in step S9). Since the openings of the recesses 114 are opened again in the etching step S7, the silicon nitride films 120 are formed bottom-up from the bottom surfaces of the recesses 114 in the next film forming step S3.

In other words, the processes of the film forming step S3, the oxidation step S5, and the etching step S7 are repeated in this order until the recesses 114 are filled with the silicon nitride films 120.

After the silicon nitride films 120 are formed in the film forming step S3, the oxidation step S5 and the etching step S7 may be repeated one or more times. As a result, the opening of the recess 114 can be formed with good controllability.

After the etching step S7 (the first etching step), a step of etching the silicon-containing film remained in an upper portion and a side wall portion of the recess 114 (a second etching step) may be further performed. For example, as shown in FIG. 2D, after the etching step S7, the silicon nitride films 120 may be remained in the upper portion and the side wall portion of the recess 114. In this state, if the silicon nitride films 120 is formed in the bottom of the recesses 114, the opening portion of the recess 114 is narrowed and embeddability may deteriorate. Therefore, after the etching step S7, the silicon nitride film 120 remained in the upper portion and the side wall portion of the recess 114 is selectively etched. Specifically, the silicon nitride film 120 is etched by the COR step and the PHT step in the same manner as in the etching step S7. In the COR process, the pressure, the flow rate ratio of gases and the processing time are controlled to selectively etch the silicon nitride film 120. As a result, the silicon nitride film 120 in the upper portion and the side wall portion of the recess 114 is removed, and the silicon nitride film 120 can be formed in the bottom-up manner with good controllability.

The COR step and the PHT step of the second etching step may be performed one or more times. As a result, the opening of the recesses 114 can be formed with good controllability.

After the etching step S7, in the state in which the openings of the recesses 114 are opened again and the silicon nitride films 120 formed on the bottom surfaces 116 are exposed, the step (second modification) of modifying the silicon nitride films 120 formed in the recesses 114 with a plasma-activated nitrogen-containing gas may be further performed. After the silicon nitride film 120 remained in the upper portion and the side wall portion of the recess 114 is selectively etched after the etching step S7, the second modification may be further performed. This makes it possible to improve the film quality of the formed silicon nitride films 120. The step of densifying a film by heat treatment may be further performed. As a result, dense silicon nitride films 120 are formed so that the film quality is improved.

A determination step may be further included to determine whether all the openings of the recesses 114 are closed by the silicon nitride films 120 in the film forming step S3 of FIG. 1 and to cause the film forming step S3 to be continued until it is determined that all the openings of the recesses 114 are closed.

As a method of determining whether the openings of the recesses 114 are closed, a determination may be made by optically measuring the cross-sectional shapes of the silicon nitride films 120 deposited on the top surfaces 112. Depending on whether the silicon nitride films 120 on the top surfaces 112 are completely closed or whether the silicon nitride are not completely closed, the state of reflection of light applied to the silicon nitride films 120 deposited on the top surfaces 112 changes. Whether or not the openings are closed by the silicon nitride films 120 may be determined based on a certain point of change in the light reflection state. However, the determination method is not limited thereto, and other methods may be used. For example, the time until the silicon nitride films 120 deposited on the top surfaces 112 are closed is measured in advance as the film formation control time and stored in a storage part. When the film formation control time elapses after initiating the film forming step S3, the next oxidation step S5 may be initiated.

A determination step may be further included to determine whether the silicon nitride films 120 closing the openings of the recesses 114 are oxidized in the oxidation step S5 of FIG. 1. The oxidation step S5 is executed until it is determined that the silicon nitride films 120 closing the openings of the recesses 114 are modified into the silicon oxide films 121. As a result, the oxidation step S5 is performed until the silicon nitride films 120 closing the openings of the recesses 114 are oxidized into the silicon oxide films 121.

As a method for determining whether the silicon nitride films 120 closing the openings of the recesses 114 are modified into the silicon oxide films 121, a determination may be made by measuring the shapes of the cross sections of the above-described silicon nitride films 120 by an optical method. Depending on whether the silicon nitride films 120 closing the openings of the recesses 114 are oxidized or whether the silicon nitride films 120 are not completely oxidized and there are non-oxidized portions of the silicon nitride films 120, the state of reflection of emitted light changes. It may be determined that the silicon nitride films 120 closing the openings of the recesses 114 are modified into the silicon oxide films 121 at a certain change point of the reflection state of the light. However, other methods may be used without being limited to this determination method. For example, the time until the silicon nitride films 120 closing the openings of the recesses 114 are modified into the silicon oxide films 121 is measured in advance as a modification control time and stored in the storage part. The next etching step S7 may be initiated when the modification control time elapses after initiating the oxidation step S5. The modification control time varies depending on the temperature of the stage (substrate). Therefore, the modification control time corresponding to the control temperature of the stage (substrate) may be measured in advance and stored in the storage part.

A determination step may be further included to determine whether the filling of the recesses 114 with the silicon nitride films 120 is completed in the filling determination step S9. As a determination method, the time until the recesses 114 are filled with the silicon nitride films 120 may be measured in advance and stored, and the time may be used as the filling determination time. In addition, the end point indicating the completion of filling with the silicon nitride films 120 may be detected by optically determining the cross sections of the silicon nitride films 120 in the recesses 114, and other methods may be used.

### [Effects]

The features and effects of the above-described film forming method ST are as follows.

### <Features>

1. A silicon nitride film is formed to close the opening of a recess 114 during a film forming step.
2. A layer above a top surface including the closed silicon nitride film is selectively oxidized.
3. The oxidized silicon oxide film is selectively etched relative to the silicon nitride film.
4. Steps of items 1 to 3 above (the film forming step S3, the oxidation step S5, and the etching step S7) are repeated until a trench structure (recess) is filled.

This makes it possible to perform filling of a high-quality silicon nitride film 120 in a recesses having a high aspect ratio while suppressing the occurrence of seams and voids.

In the film forming method ST of FIG. 1, an example of filling a silicon nitride film as an example of a silicon-containing film in a recess 114 of a trench structure has been described, but the silicon-containing film may be a film containing silicon and nitrogen. The film containing silicon and nitrogen may be any one of SiN film, SiCN film, SiBN film, SiON film, and SiOCN film. In addition, the silicon-containing film may be a Si film. In either case, the film is oxidized in the oxidation step S5. For example, when the silicon-containing film is a Si film, the Si film is oxidized into a SiO film in the oxidation step S5. Even in this case, it is possible to take a selective ratio of the SiO film to the Si film in the etching step S7, and thus it is possible to selectively etch the SiO film.

In the case where the silicon-containing film is a SiON film, the SiON film is turned into a SiO film when being oxidized. In addition, even if there is a portion of the SiO film in which N remains as SiON, the amount of N component in the film is small if the film is sufficiently modified. Thus, the selective ratio of the SiO film to the SiON film may be obtained, and thus it is possible to selectively etch the SiO film.

### [Film Forming Time and Film Thickness]

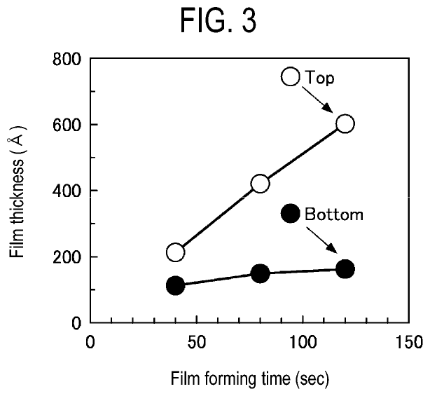

FIG. 3 is a diagram showing the relationship between time (film forming time) and film thickness in the film forming step S3, and is the experimental result of forming a silicon nitride film by the film forming method ST. The horizontal axis of FIG. 3 represents the elapsed time from the initiation of the film forming step S3 as “film forming time (sec)”, and the vertical axis represents the thickness of a silicon nitride film 120 formed in a recess 114 as “thickness (A)”. “Top” indicated by ∘ indicates the thickness (film thickness) of the thickest portion of the silicon nitride film 120 deposited on the upper layer from the top surface 112 of the recess 114. “Bottom” indicated by • indicates the thickness (film thickness) of the thickest portion of the silicon nitride film 120 deposited on the bottom surface 116 of the recess 114 from the bottom surface 116. The process conditions of this test are as follows.

### <Process Condition>

Film forming gases (flow rate ratio): SiH₄, NH₃, and Ar (flow rate ratio of SiH₄:NH₃=20:10 to 20:20)

Pressure: 5 Pa to 50 Pa

Temperature: 200 degrees C. to 600 degrees C.

Power: 1,500 W to 4,500 W

According to the experimental results shown in FIG. 3, the film thickness of “Top” was thicker than that of “Bottom” regardless of the film forming time. In addition, as the film forming time increased, the difference between the film thickness of “Top” and the film thickness of “Bottom” was increased, and the growth speed of the silicon nitride film of “Top” relative to the silicon nitride film of “Bottom” was increased.

### [Film Forming Time and Pressure]

If it is possible to increase the film thickness of “Top” indicate in FIG. 3 in a short period of time, it is possible to close the opening of the recess 114 in a short period of time with the silicon-containing film. This makes it possible to increase the operation rate of the processing apparatus that executes the film forming step S3 and to improve the throughput, which is advantageous.

Therefore, it is preferable to control the range of the pressure and/or the gas flow rate ratio to an optimum value such that the film thickness of “Top” can be increased in a short period of time to close the opening of the recess 114 with the silicon-containing film in a short period of time.

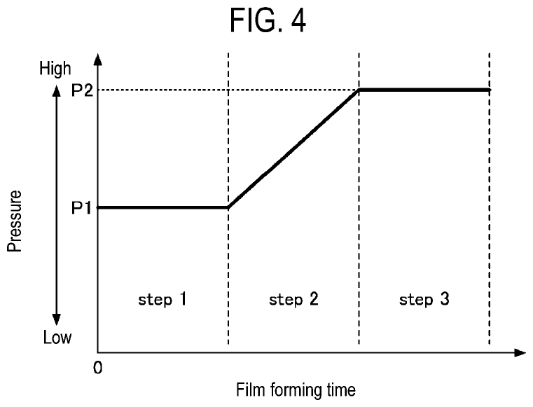

FIG. 4 is a diagram showing the relationship between film forming time and pressure according to the embodiment. The horizontal axis of FIG. 4 represents the film forming time, and the vertical axis represents the pressure inside the processing container of the processing apparatus that executes the film forming step S3. When the film forming time is divided into step 1, step 2, and step 3, in the initial stage step 1 of the film forming step S3, the pressure is set to a preset pressure P1 and the pressure P1 is controlled to be maintained. In the middle stage step 2, the pressure is controlled to be a pressure P2 higher than the pressure P1. In the late stage step 3 in which the pressure reaches the pressure P2, the pressure is controlled to be maintained at the pressure P2.

In such control, the film forming time is divided into multiple steps, and the pressure is controlled stepwise according to the initial, middle, and late stages of the film formation. For example, after the silicon-containing film is formed on the bottom surface 116 to some extent in the initial stage step 1, the pressure condition is changed so that the silicon-containing film in the upper layer of the top surface 112 is grown to be faster in the middle stage step 2, and the pressure is controlled to a target pressure. After the pressure is controlled to the target pressure in the middle stage step2, the target pressure is maintained in the late stage step3. In this way, the pressure is controlled stepwise. This makes it possible to more quickly close the opening of the recess 114 by the silicon-containing film while promoting the filling of the silicon-containing film in the bottom surface of the recess 114. However, the step of forming the silicon-containing film is not limited to controlling the pressure stepwise, and the pressure may be controlled to change continuously.

### [Film Forming Time and Gas Flow Rate Ratio]

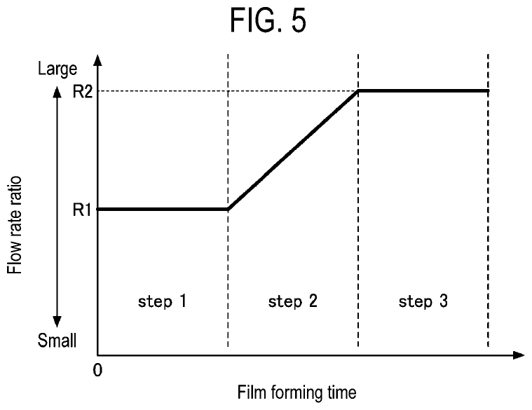

In the film forming step S3, the flow rate ratio of the silicon-containing gas may be controlled stepwise. FIG. 5 is a diagram showing the relationship between film forming time and gas flow rate ratio according to an embodiment. The horizontal axis of FIG. 5 represents the film forming time, and the vertical axis represents the flow rate ratio of, for example, NH₃ gas (and/or N₂ gas) to SiH₄ gas as a gas supplied into the processing container in which the film forming step S3 is performed. When the film forming time is divided into step 1, step 2, and step 3, in the initial stage step 1 of the film forming step S3, the flow rate ratio of NH₃ gas (and/or N₂ gas) to SiH₄ gas is set to a preset flow rate ratio R1, and is controlled to maintain the flow rate ratio R1. In the middle stage step2, the flow rate ratio is controlled to be a flow rate ratio R2 higher than the flow rate ratio R1. In the late stage step 3 in which the flow rate ratio of the gas reaches the flow rate ratio R2, the flow rate ratio is controlled to maintain the flow rate ratio R2. By controlling the flow rate ratios of gases including silicon stepwise in this manner, it is possible to more quickly close the opening of the recess 114 with the silicon-containing film in the recess 114. However, the step of forming the silicon-containing film is not limited to controlling the flow rate ratio stepwise, and the flow rate ratio may be controlled to change continuously. The flow rate ratio R1 and the flow rate ratio R2 are not limited to the flow rate ratio of NH₃ gas (and/or N₂) to SiH₄ gas. For example, the flow rate ratio R1 and the flow rate ratio R2 may be the flow rate ratio of SiH₄ gas to the total mixed gas including the SiH₄ gas (all gases to be supplied).

### [Film Forming System]

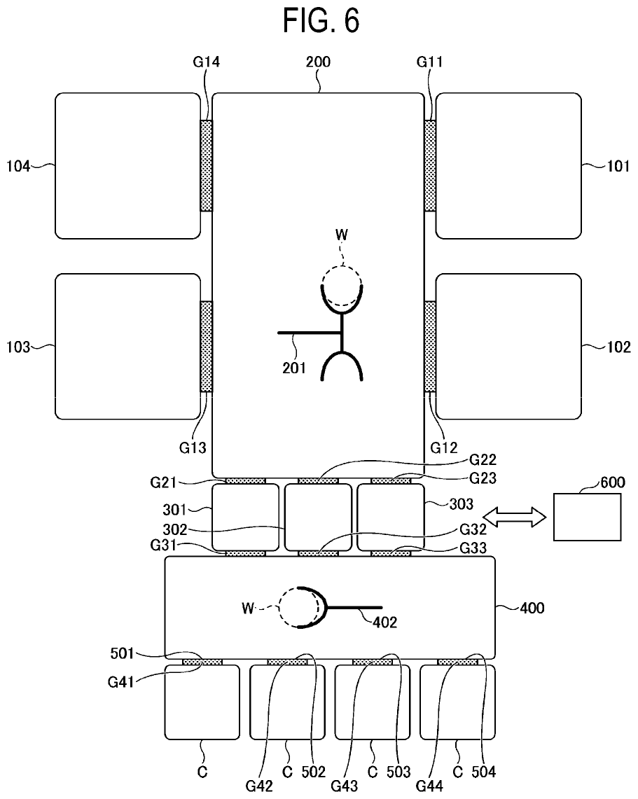

FIG. 6 is a view illustrating a configuration example of a film forming system according to an embodiment. The film forming system includes a processing apparatus that executes the film forming method ST of the present disclosure. However, the configuration of the film forming system in FIG. 6 is an example, and other configurations are possible.

The film forming system includes processing apparatuses 101 to 104, a vacuum transport chamber 200, load-lock chambers 301 to 303, an atmospheric transport chamber 400, load ports 501 to 504, and a controller 600.

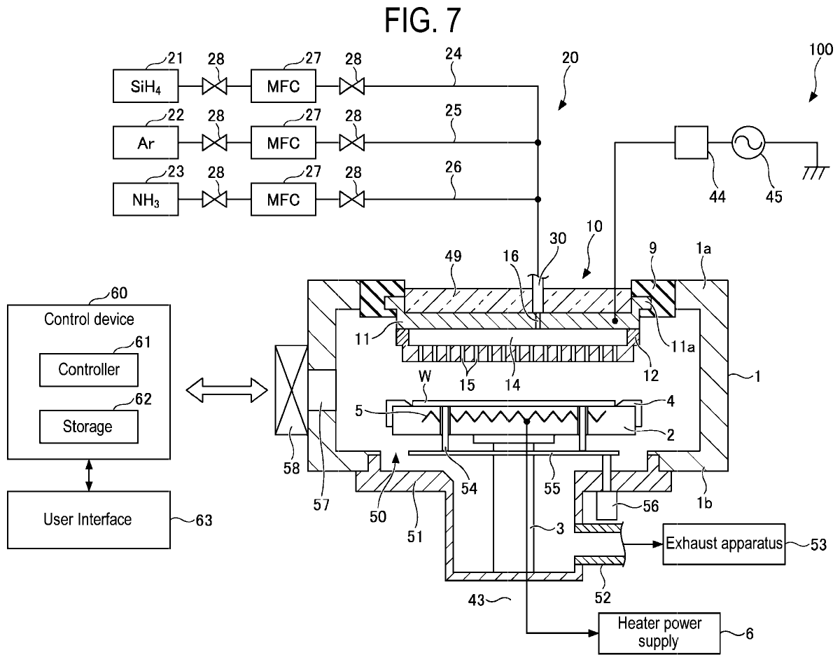

The processing apparatuses 101 to 104 are connected to the vacuum transport chamber 200 via gate valves G11 to G14, respectively. The interiors of the processing apparatuses 101 to 104 are depressurized to a predetermined vacuum atmosphere, and desired processes are performed on wafers W therein. The processing apparatus 101 is an example of a first processing apparatus configured to execute the film forming step S3 of FIG. 1 so as to form a silicon-containing film in a recess in a substrate W. The processing apparatus 102 is an example of a second processing apparatus configured to perform the oxidation step S5 (modifying step) of FIG. 1 so as to partially oxidize (modify) a silicon-containing film formed in the recess. The processing apparatuses 103 and 104 are examples of a third processing apparatus configured to perform the etching step S7 of FIG. 1 and selectively etch an oxidized (modified) silicon-containing film. For example, the processing apparatus 103 executes a COR step and the processing apparatus 104 performs a PHT step. The film forming step S3 and the oxidation step S5 may be executed in the processing apparatus 101. In this case, the processing apparatus 102 may be an apparatus that performs the same process as the processing apparatus 101, or may be an apparatus that performs a different process. A configuration example of the processing apparatus 101 will be described later with reference to FIG. 7.

The interior of the vacuum transport chamber 200 is depressurized to a predetermined vacuum atmosphere. The vacuum transport chamber 200 is provided with a transport mechanism 201 capable of transporting substrates W in the depressurized state. The transport mechanism 201 transports substrates W to the processing apparatuses 101 to 104 and the load-lock chambers 301 to 303. The transport mechanism 201 has, for example, two transport arms. However, there may be a single transport arm.

The load-lock chambers 301 to 303 are connected to the vacuum transport chamber 200 via gate valves G21 to G23, respectively, and connected to the atmospheric transport chamber 400 via the gate valves G31 to G33, respectively. The interiors of the load-lock chambers 301 to 303 are configured to be switchable between an air atmosphere and a vacuum atmosphere.

The interior of the atmospheric transport chamber 400 has an air atmosphere, and, for example, a downflow of clean air is formed in the atmospheric transport chamber 400. In the atmospheric transport chamber 400, an aligner (not illustrated) is provided to perform alignment of substrates W. In addition, the atmospheric transport chamber 400 is provided with a transport mechanism 402. The transport mechanism 402 has, for example, a single transport arm. However, there may be two or more transport arms. The transport mechanism 402 transports substrates W to the load-lock chambers 301 to 303, to carriers C in the load ports 501 to 504 to be described later, and to the aligner.

The load ports 501 to 504 are provided in the wall of a long side of the atmospheric transport chamber 400. Carriers, each of which is a carrier C accommodating a substrate W or an empty carrier C, are mounted in the load ports 501 to 504 through the gate valves G41 to G44, respectively. As the carriers C, for example, front opening unified pods (FOUPs) may be used.

The controller 600 controls each part of the film forming system. For example, the controller 600 executes the operations of the processing apparatuses 101 to 104, the operations of the transport mechanisms 201 and 402, the opening/closing of the gate valves G11 to G14, G21 to G23, G31 to G33, and G41 to G44, the switching of the atmospheres in the load-lock chambers 301 to 303, and the like. The controller 600 may be, for example, a computer.

### [Film Forming Apparatus]

FIG. 7 is a view illustrating a configuration example of a film forming apparatus 100 according to an embodiment. The film forming apparatus 100 is an apparatus that executes the film forming step S3 to form a silicon-containing film in a recess in a substrate W within a processing container 1 in a depressurized state, and is an example of the processing apparatus 101 of FIG. 6. The film forming apparatus 100 may be an apparatus that performs the oxidation step S5 following the film forming step S3. That is, the oxidation step S5 may be executed by the processing apparatus 101 a configuration example of which is the film forming apparatus 100 of FIG. 7, and may be executed in the processing apparatus 102 different from the processing apparatus 101.

However, the configuration of the film forming apparatus 100 in FIG. 7 is an example, and any type of plasma processing apparatus, such as a capacitively coupled plasma (CCP) type, an inductively coupled plasma (ICP) type, a micro surface wave plasma type, an electron cyclotron resonance plasma (ECR) type, or a helicon wave plasma (HWP) type, is applicable as the film forming apparatus. Even a thermal CVD apparatus that does not use plasma is applicable as long as a process condition is to close an opening by film formation. In addition, any of a single-wafer apparatus that processes substrates one by one, and a batch apparatus and a semi-batch apparatus that collectively process plural substrates are applicable as the film forming apparatus.

The film forming apparatus 100 includes a processing container 1 formed in a substantially cylindrical shape from aluminum or the like and having an anodized inner wall surface. The processing container 1 is grounded. A susceptor 2 is provided inside the processing container 1. The susceptor 2 is supported by a substantially cylindrical support member 3 provided in the central lower portion of the processing container 1. The susceptor 2 is a stage for horizontally supporting a substrate W, and is made of, for example, a ceramic material such as aluminum nitride (AlN), or a metal material such as aluminum or a nickel alloy. The susceptor 2 is grounded via the support member 3.

A guide ring 4 for guiding a substrate W is provided on the outer edge of the susceptor 2. A heater 5 made of a high melting point metal such as molybdenum is embedded in the susceptor 2. A heater power supply 6 is connected to the heater 5. The heater 5 heats the substrate W supported by the susceptor 2 to a predetermined temperature with power supplied from the heater power supply 6.

A shower head 10 is provided on the ceiling wall 1a of the processing container 1 via an insulating member 9. The shower head 10 in this embodiment is a premix-type shower head and includes a base member 11 and a shower plate 12. The outer peripheral portion of the shower plate 12 is fixed to the base member 11.

The shower plate 12 has a flange shape, and a recess is formed inside the shower plate 12. That is, a gas diffusion space 14 is formed between the base member 11 and the shower plate 12. A flange portion 11a is formed on the outer peripheral portion of the base member 11, and the base member 11 is supported by the insulating member 9 via the flange portion 11a.

Gas ejection holes 15 are formed in the shower plate 12. A gas introduction hole 16 is formed near the approximate center of the base member 11. The gas introduction hole 16 is connected to a gas supply mechanism 20 via a pipe 30.

The gas supply mechanism 20 includes a silicon-containing gas source 21, a rare gas source 22, and a nitrogen-containing gas source 23. In the present embodiment, the silicon-containing gas is, for example, SiF₄ gas. In the present embodiment, the rare gas is, for example, Ar gas. In the present embodiment, the nitrogen-containing gas is, for example, ammonia (NH₃) gas.

The source 21 is connected to the pipe 30 via a valve 28, a mass flow controller (MFC) 27, and a valve 28. The source 22 is connected to the pipe 30 via a valve 28, a mass flow controller (MFC) 27, and a valve 28. The source 23 is connected to the pipe 30 via a valve 28, a mass flow controller (MFC) 27, and a valve 28. The processing gas supplied into the gas diffusion space 14 through the pipe 30 diffuses in the gas diffusion space 14 and is ejected into the processing container 1 through the gas ejection holes 15 in a shower shape.

A radio frequency (RF) power supply 45 is connected to the base member 11 via a matcher 44. The RF power supply 45 supplies RF power for plasma generation to the base member 11 via the matcher 44. The RF power supplied to the base member 11 is radiated into the processing container 1 via the intermediate member 13 and the shower plate 12. By the RF power radiated into the processing container 1, the processing gas supplied into the processing container 1 is plasmatized. In the present embodiment, the shower head 10 also functions as the upper electrode of the parallel plate electrodes. Meanwhile, the susceptor 2 also functions as a lower electrode of the parallel plate electrodes.

A substantially circular opening 50 is formed in the substantially central portion of the bottom wall 1b of the processing container 1. An exhaust chamber 51 is provided in the opening 50 in the bottom wall 1b to cover the opening 50 and protrude downward. The exhaust chamber 51 is grounded via the processing container 1. An exhaust pipe 52 is connected to a side wall of the exhaust chamber 51. An exhaust apparatus 53 including a vacuum pump is connected to the exhaust pipe 52. The interior of the processing container 1 may be depressurized to a predetermined degree of vacuum by the exhaust apparatus 53.

The susceptor 2 is provided with lift pins 54 (for example, three) for raising and lowering a substrate W to protrude and sink with respect to the surface of the susceptor 2. The plurality of lift pins 54 are supported by a support plate 55. The support plate 55 is raised and lowered by driving the drive mechanism 56. As the support plate 55 is raised and lowered, the lift pins 54 are raised and lowered.

The side wall of the processing container 1 is provided with a transport port 57 for transporting the substrate W to and from a substrate transport chamber (not illustrated) provided adjacent to the processing container 1. The transport port 57 is opened and closed by a gate valve 58.

The film forming apparatus 100 includes a control device 60. The control device 60 is, for example, a computer, and includes a controller 61 and a storage part 62. The storage part 62 stores in advance programs or the like for controlling various processes to be executed in the film forming apparatus 100. The controller 61 controls each part of the film forming apparatus 100 by reading and executing the programs stored in the storage part 62.

The programs stored in advance in the storage part 62 may be recorded in a computer-readable storage medium and installed in the storage part 62 from the storage medium. The computer-readable storage medium is, for example, a hard disk (HD), a flexible disk (FD), a compact disk (CD), a magneto-optical disk (MO), a memory card, or the like.

A user interface 63 including a keyboard for an operator to perform an input operation of commands or the like in order to manage the film forming apparatus 100, a display for visualizing and displaying the operating state of the film forming apparatus 100, or the like is connected to the control device 60.

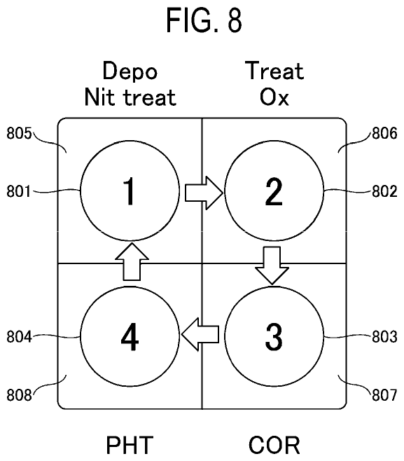

In the system of FIG. 6, the processing apparatuses 101 to 104 are explained as the processing apparatuses corresponding to the film forming step, the modification step, the COR step and the PHT step, respectively, but the present disclosure is not limited thereto. For example, as shown in FIG. 8, the substrates W may be processed in one processing apparatus. For example, the processing apparatus shown in FIG. 8 includes multiple stages 801 to 804 in a processing container, and the substrates W (e.g., 4 substrates) are respectively mounted on the stages 801 to 804. The processing apparatus further includes multiple processing space 805 to 808 corresponding to the stages 801 to 804, respectively. The film forming step, the modification step, the COR step and the PHT step is performed in the processing spaces, respectively, to fill the silicon-containing film in the recess formed on the substrates W. In this way, since one processing apparatus may execute multiple processes with respect to the multiple substrates W, the productivity is increased. The processing space 805 is an example of a first processing space performing the film forming step. The processing space 806 is a second processing space performing the modification step. The processing space 807 is a third processing space performing the COR step. The processing space 808 is a fourth processing space performing the PHT step.

As described above, according to the film forming method and the film forming system of the present embodiment, it is possible to improve the filling performance of a silicon-containing film in a recess formed in a substrate.

The film forming method and the film forming apparatus according to the embodiments disclosed herein should be considered as being exemplary in all respects and not restrictive. The embodiments may be modified and improved in various forms without departing from the scope and spirit of the appended claims. The matters described in the plurality of embodiments may take other configurations within a non-contradictory range, and may be combined within a non-contradictory range.

According to an aspect, it is possible to improve the filling performance of a silicon-containing film in a recess formed in a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
preparing a substrate having a recess within a processing container;
forming a silicon-containing film on the substrate by activating a silicon-containing gas with plasma and supplying the activated silicon-containing gas to the substrate;
partially modifying the silicon-containing film after the silicon-containing film closes an opening of the recess; and
selectively etching the modified silicon-containing film.

2. The film forming method of claim 1, wherein the forming the silicon-containing film, the partially modifying the silicon-containing film, and the selectively etching the modified silicon-containing film are performed in this order one or more times.

3. The film forming method of claim 1, wherein, after the forming the silicon-containing film, the partially modifying the silicon-containing film and the selectively etching the modified silicon-containing film are performed in this order one or more times.

4. The film forming method of claim 1, wherein, in the forming the silicon-containing film, a pressure in the processing container of a processing apparatus configured to form the silicon-containing film is controlled stepwise or continuously.

5. The film forming method of claim 4, wherein the forming the silicon-containing film includes:
controlling the pressure in the processing container of the processing apparatus configured to form the silicon-containing film to a first pressure; and
controlling the pressure in the processing container of the processing apparatus configured to form the silicon-containing film to a second pressure higher than the first pressure.

6. The film forming method of claim 1, wherein, in the forming the silicon-containing film, a flow ratio of the silicon-containing gas to a mixed gas of plural gases including the silicon-containing gas is controlled stepwise or continuously.

7. The film forming method of claim 6, wherein the forming the silicon-containing film includes:
controlling a flow rate ratio of the silicon-containing gas to the mixed gas of the plural gases including the silicon-containing gas to a first flow rate ratio; and
controlling the flow rate ratio of the silicon-containing gas to the mixed gas of the plural gases containing the silicon-containing gas to a second flow rate ratio larger than the first flow rate ratio.

8. The film forming method of claim 1, wherein, in the partially modifying the silicon-containing film, the silicon-containing film is partially oxidized.

9. The film forming method of claim 1, wherein, in the selectively etching the modified silicon-containing film, the modified silicon-containing film is removed to form the opening of the recess.

10. The film forming method of claim 1, wherein, in the selectively etching the modified silicon-containing film, the silicon-containing film is removed without using plasma.

11. The film forming method of claim 1, wherein the selectively etching the modified silicon-containing film includes:
forming a reaction by-product by supplying a fluorine-containing gas and a nitrogen-containing gas to the substrate to react with the modified silicon-containing film; and
removing the reaction by-product.

12. The film forming method of claim 11, wherein, in the removing the reaction by-product, the reaction by-product is sublimated and removed by heat treatment.

13. The film forming method of claim 11, wherein, in the removing the reaction by-product, a temperature of a stage on which the substrate is placed is controlled to 50 degrees C.

14. The film forming method of claim 1, further comprising:
further etching the silicon-containing film on an upper portion and a side wall portion of the recess after the selectively etching the modified silicon-containing film.

15. The film forming method of claim 14, wherein the further etching the silicon-containing film includes:
forming a reaction by-product by supplying a fluorine-containing gas and a nitrogen-containing gas to the substrate to react with the modified silicon-containing film; and
removing the reaction by-product.

16. The film forming method of claim 15, wherein the forming the reaction by-product and the removing the reaction by-product are performed one or more times.

17. The film forming method of claim 1, further comprising:
modifying the silicon-containing film formed in the recess by a plasma-activated nitrogen-containing gas after the selectively etching the modified silicon-containing film.

18. The film forming method of claim 1, wherein the silicon-containing film is a film containing silicon and nitrogen.

19. The film forming method of claim 18, wherein the film containing the silicon and the nitrogen is any one of SiN film, SiCN film, SiON film, and SiOCN film.

20. The film forming method of claim 1, wherein the silicon-containing film is a Si film.

21. The film forming method of claim 1, wherein the substrate includes recesses, and
the film forming method further comprises:
determining whether the silicon-containing film closes openings of the recesses,
wherein, in the partially modifying the silicon-containing film, modification of the silicon-containing film is initiated when it is determined that the silicon-containing film closes all the openings of the recesses in the determining whether the silicon-containing film closes the openings of the recesses.

22. The film forming method of claim 1, further comprising:
determining whether the silicon-containing film closing the opening of the recess is oxidized,
wherein, in the selectively etching the modified silicon-containing film, etching of the silicon-containing film is initiated when it is determined that the silicon-containing film closing the opening of the recess is oxidized in the determining whether the silicon-containing film closing the opening of the recess is oxidized.

23. The film forming method of claim 1, wherein the forming the silicon-containing film and the partially modifying the silicon-containing film are performed in a same processing apparatus.

24. A film forming system comprising:
processing apparatuses,
wherein the processing apparatuses include:
a first processing apparatus configured to execute forming a silicon-containing film on a substrate having a recess by activating a silicon-containing gas with plasma and supplying the activated silicon-containing gas to the substrate;
a second processing apparatus configured to execute partially modifying the silicon-containing film after the silicon-containing film closes an opening of the recess; and
a third processing apparatus configured to execute selectively etching the modified silicon-containing film,
wherein the first processing apparatus and the second processing apparatus are same or different processing apparatuses, and the first processing apparatus and the third processing apparatus are different processing apparatuses, and the second processing apparatus and the third processing apparatus are different processing apparatuses.

25. A film forming system comprising:
a processing apparatus configured to process substrates,
wherein the processing apparatus includes:
stages configured to mount the substrates; and
processing spaces corresponding to the stages, and
wherein the processing spaces includes:
a first processing space configured to execute forming a silicon-containing film on the substrate having a recess by activating a silicon-containing gas with plasma and supplying the activated silicon-containing gas to the substrate;
a second processing space configured to execute partially modifying the silicon-containing film after the silicon-containing film closes an opening of the recess;
a third processing space configured to execute forming a reaction by-product by supplying a fluorine-containing gas and a nitrogen-containing gas to the substrate to react with the modified silicon-containing film; and
a fourth processing space configured to execute removing the reaction by-product.
